(19) United States
(12) Patent Application Publication
(10) Pub. No.: US 2006/0279298 A1
(43) Pub. Date: Dec. 14, 2006

(54) Measurement method for compensation and verification

(75) Inventors: Eiji Tsuchida, Tokyo (JP); Yasushi Okawa, Tokyo (JP)

Correspondence Address: Paul D. Greeley;Ohlandt, Greeley, Ruggiero & Perle, L.L.P., 10th Floor, One Landmark Square, Stamford, CT, 06901-2682, US

(73) Assignee: Agilent Technologies, Inc.

(21) Appl. No.: 11/396,865

(22) Filed: Apr. 3, 2006

(30) Foreign Application Priority Data
Apr. 28, 2005 (JP) 2005-131749

(51) Int. Cl. G01R 31/02

(52) U.S. Cl. 324/754; 324/647

(57) ABSTRACT

A measurement method for compensation for short-circuit compensation or load compensation or a measurement method for verification uses a device for measuring impedance by probing an impedance standard substrate using contact probes, and comprises a step whereby contact sites for probing the impedance standard substrate are input and an alarm is displayed when the number of contacts with the contact sites exceeds a predetermined limit.

### 1. FIELD OF THE INVENTION

The present invention relates to compensation technology when the impedance of a device under test (DUT) is measured by bringing the DUT into contact with an electrode using a probe, probe needle, membrane probe, or other type of contact probe, and in particular, relates to a measurement system and method for compensation when the impedance of a DUT on a semiconductor wafer is measured.

### 2. DISCUSSION OF THE BACKGROUND ART

When measuring high-frequency signals on a semiconductor wafer (the present specification simply refers to a semiconductor wafer as a wafer hereafter) using a wafer prober, compensation from the measuring device to the needle tip must be applied using an impedance compensation substrate called an Impedance Standard Substrate (ISS). Cascade Microtech, Inc. “Impedance Standard Substrates to support all of your high-frequency probing applications”, 2004, Catalog is a known example of an ISS. This ISS comprises a pad (electrode) group for through (THRU) compensation, a pad group for short-circuit (SHORT) compensation, and a pad group for load (LOAD) compensation on a 1.5×1 centimeter substrate. Each pad group is composed of a pattern that is appropriate for the respective measurement purpose, and is formed of multiple pads as a countermeasure to the wear that occurs as a result of probing using probe needles or other contact probes. The term contact probe in the present Specification means a tool that can probe a pad with its size of several tens of microns, and examples are probe needles, probes, and membrane probes. SG-type (Signal-Ground type), and GSG (Ground-Signal-Ground)-type compensation patterns are examples of load compensation patterns of impedance standard substrates. Moreover, compensation patterns are lined up in rows of two such that a measurement system that uses four or six contact probes can be constructed for RF signal compensation.

However, in recent years, attention has been focused on methods for measuring the capacitance of insulation films during the semiconductor production process, and in particular, on methods for measuring capacitance-voltage properties. Examples of insulation films in the semiconductor insulation process are an MIS (Metal Insulator Silicon)-CAP (CAPacitor) made from the insulation film of a transistor, an MOS (Metal Oxide Silicon)-CAP made from the insulation film of a transistor, an MIS-FET gate insulation film, an MOS-FET gate insulation film, and an MOS capacitor gate insulation film. It should be noted that gate insulation films include gate oxide films.

As cited in Agilent Technologies, Product note: “Agilent Technologies, C-V property evaluation of gate oxide film of MOS capacitor by Agilent Technologies 4294A, Product Note 4294-3”, Jun. 25, 2003, Product Notes, pp. 6 and 7, when an insulation film is measured, it is necessary to apply OPEN/SHORT/LOAD compensation at the tip of the contact probe using an impedance standard substrate (ISS) in order to reduce the error that is generated by a measurement system that comprises probe needles or other contact probes before capacitance is measured using an impedance measurement device, such as an impedance analyzer (for instance, Agilent 4284A, Agilent 4285A, or Agilent 4294A made by Agilent Technologies).

However, degradation and contamination of the tips of the contact probes and degradation of the pad surface (touch-down imprint or oxidation) increase the contact resistance and the compensation is incorrect. Therefore, special precautions and training are necessary for the compensation procedure. SUMMARY OF THE INVENTION

An apparatus or method for execution and support such that open-circuit/short-circuit/load compensation using an impedance standard substrate can be easily performed.

An apparatus or method comprising an algorithm for performing verification measurement to find the optimum contact conditions and then automatically executing compensation measurement and performing compensation in order to execute and support the above-mentioned compensation operation.

An apparatus or method with which the number of contacts with a pad on an impedance standard substrate is counted and an alarm goes off when the number of contacts exceeds the limit in order to conduct the above-mentioned compensation operation with stability.

A program with which the optimum conditions for contact by the contact probe with the desired pad during verification measurement can be set for each pad for short-circuit compensation and load compensation, and further, to provide an apparatus or method with which offset in directions X, Y, and Z can be set as the optimum contact conditions.

An apparatus or method for displaying the measurement results after verification measurement in graph form by frequency.

A measurement method for compensation or verification for short-circuit compensation or load compensation using a device for measuring impedance by probing an impedance standard substrate with a contact probe, wherein the contact site for probing the impedance standard substrate is input and an alarm is displayed when the number of contacts with the contact site exceeds a predetermined limit.

The number of contacts with the contact site is stored in a memory of a computer for controlling the contact probe and the device for measuring impedance.

The amount of offset for probing is specified after the step whereby the contact site is input. The specification of the amount of offset includes the amount of offset in directions X, Y, and Z. The amount of offset is specified, differentiating between whether it is for short-circuit compensation or load compensation. The measurement results at a predetermined frequency are displayed in graph form after the verification measurement.

A measurement method for compensation at each compensation mode of open-circuit compensation, short-circuit compensation, and load compensation using a contact probe and an impedance standard substrate and a device for measuring the impedance, whereby a preliminary measurement of impedance is performed when conducting the compensation measurement of each of the three compensation modes and an impedance measurement for compensation calculation is performed when these measurement values are within a first predetermined limit range. An alarm is displayed during the compensation modes of the short-circuit compensation and load compensation before the preliminary impedance measurement if the number of contacts with the contact site probed by the contact probe exceeds a second predetermined limit.

A measurement method for compensation and verification in each compensation mode of open-circuit compensation, short-circuit compensation, and load compensation using a contact probe and an impedance standard substrate and a device for measuring impedance whereby first, a verification measurement is performed and if the results of verification measurement are within a predetermined limit range, a compensation measurement is performed using the contact conditions relating to the contact probe of the impedance standard substrate used for the verification measurement.

The contact conditions include specification of the contact site and specification of the amount of offset in directions X, Y, and Z for both short-circuit and load compensation.

As previously described, open-circuit/short-circuit/load compensation operations using an impedance standard substrate can be easily performed by the present invention. In particular, the present invention comprises an algorithm for performing a verification measurement, finding the optimum contact conditions, then executing an automatic compensation measurement, and performing compensation; therefore, the operator can efficiently perform the compensation operation.

Moreover, the number of contacts with a pad on an impedance standard substrate are counted and an alarm goes off if the limit is exceeded; therefore, the compensation operation can be easily performed because there is no need for the operator to count the number of contacts with a pad.

Furthermore, the optimum contact conditions with the desired pad in the verification measurements can be set for each pad for short-circuit compensation and load compensation; therefore, the operator can perform compensation with stability.

The optimum contact conditions can be specified as offset in directions X, Y, and Z for both short-circuit compensation and load compensation. Therefore, although the offset could only be applied uniformly to the standard coordinates of the prober in the past, in addition to being able to specify the offset for each compensation mode, it is possible to specify the X and Y coordinates on a pad as well as specify an overdrive of the contact probe as the offset in the Z direction. As a result, compensation measurement can be performed with stability and high precision.

The measurement results are displayed in graph form for each frequency after verification measurement; therefore, the results can be easily understood by the operator.

### BRIEF DESCRIPTION OF THE DRAWINGS

FIG. 1 is a flow chart showing the algorithm of the program that is an embodiment of the present invention. FIG. 2 is a flow chart showing some details of the flow chart in FIG. 1.

FIG. 3 is a flow chart showing some details of the flow chart in FIG. 1.

FIG. 4 is a drawing that describes some screens of the program of the present invention.

FIG. 5 is a drawing that describes some screens of the program of the present invention.

FIG. 6 is a drawing that describes some screens of the program of the present invention.

FIG. 7 is a schematic diagram showing the measurement system of the present invention.

### DETAILED DESCRIPTION OF THE PREFERRED EMBODIMENT

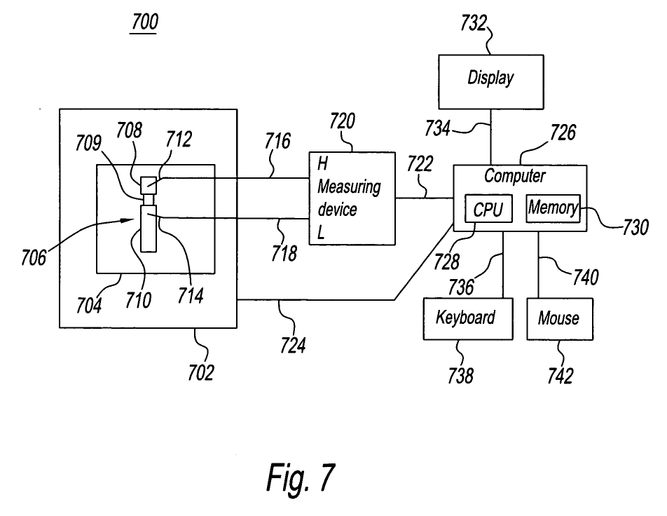

Referring to the block diagram in FIG. 7, a measurement system 700 for compensation using an impedance standard substrate (ISS) is a preferred embodiment of the present invention and will be described taking a pattern 706 for SG-type load compensation on an ISS as an example. An S-side pad 708 of pattern 706 on an ISS 704 is probed by a contact probe 712 via a cable 716 from the H-side terminal of a measuring device 720 for measuring impedance, while a G-side pad 710 of pattern 706 is probed by a contact probe 714 via a cable 718 from the L-side terminal of measuring device 720 and the ISS is thereby measured. Measuring device 720 is controlled by being connected to a computer 726 by GP-IB, or another control bus 722.

Computer 726 is a PC or other computer and houses a CPU 728 as an processing unit and a memory 730 in which programs and data are stored. Memory 730 can be a RAM, ROM, flash memory, or other semiconductor memory, or it can be a hard disk drive (HDD) or other storage device. Moreover, the computer comprises a CRT, LCD or other display 732, a keyboard 738, and a mouse 742 as the input/output equipment, and each of these is connected to computer 726 by cables 734, 736, and 740, respectively. A track ball, touch pad, touch panel bonded to display 732, and the like can be used in place of the keyboard and mouse.

It should be noted that ISS (704) and contact probes 712 and 714 are disposed inside the prober, that is wafer prober 702, for simple, high-precision alignment. Prober 702 is controlled by being connected to a control bus 724 from computer 726.

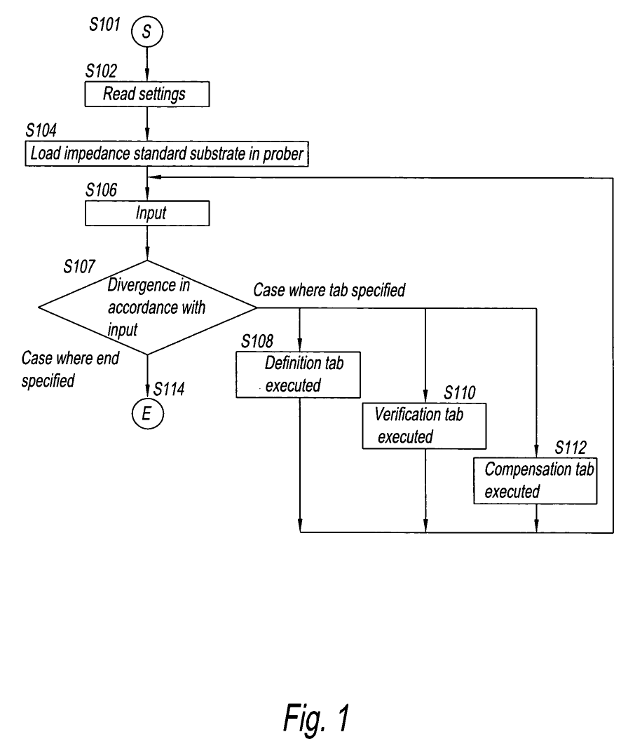

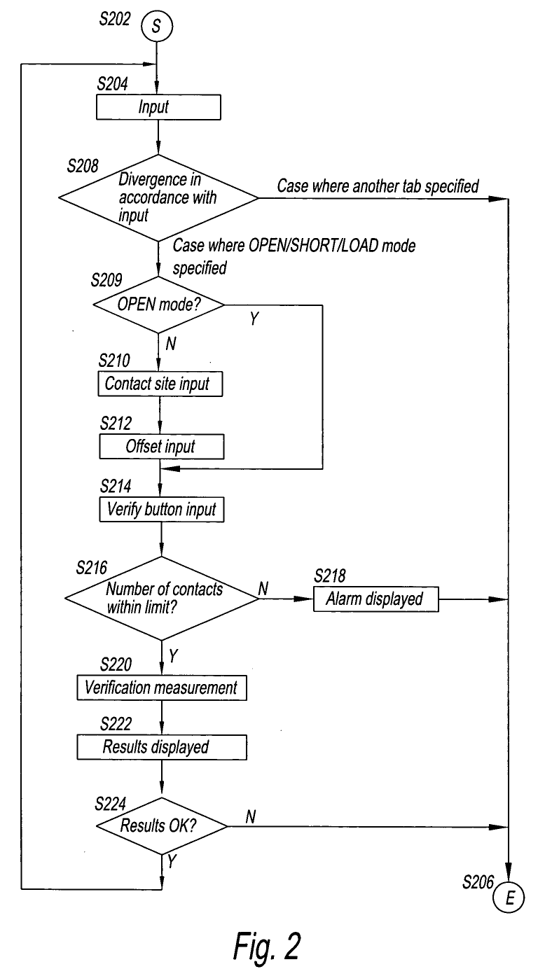

Next, the algorithm for the program that is executed by the apparatus that executes and supports compensation by the present invention will be described while referring to FIGS. 1 through 3. FIG. 1 shows the main algorithm for this program. That is, this program starts at step S101, and each setting is read for the specified file at step S102. These readings include the contact history of the ISS that will be used, the contact setting details, the limit settings, and the like. Then ISS (704) is loaded by command into prober 702 at a position where probing is possible at step S104. Then input from the operator is applied at step S106 and the procedure diverges at step S107 in accordance with this input.

That is, when the execution of a tab screen, which is described later, is specified, the routine that controls each tab screen is executed in accordance with the specified tab screen. When a definition tab (a tab screen for setting each type of parameter) is specified by mouse 742 or keyboard 738, the program proceeds to step S108, the execution routine of the definition tab is executed, and the program returns to step S106; when a verification tab (the tab screen for executing verification) is specified, the program proceeds to S110, the execution routine of the verification tab is executed, and the program returns to step S106; and when a compensation tab (the tab screen for executing compensation) is specified, the program proceeds to step S112, the execution routine of the compensation tab is executed, and the program returns to step S106. Moreover, once the input results at step S106 indicate that the program has been completed, the program proceeds to Step S114 and the program ends.

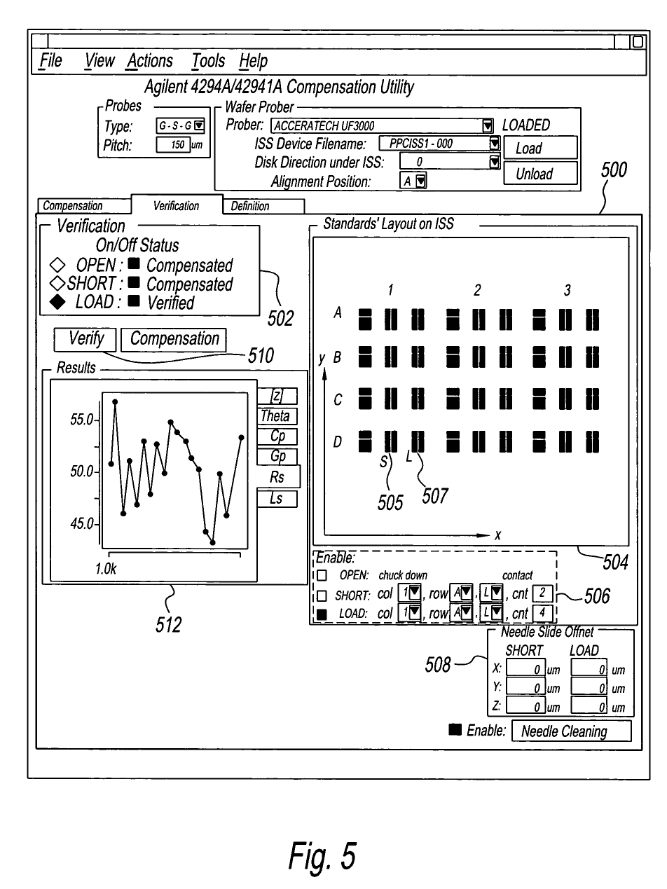

Next, the algorithm at the verification tab at step S110 will be described using the flow chart for the algorithm in FIG. 2 and a verification tab screen 500 in FIG. 5. First, the execution routine of the verification tab starts at step S202 and the operator inputs at step S204. That is, the operator selects whether to perform OPEN (open-circuit) mode verification (also called verify), SHORT (short-circuit) mode verification, or LOAD (load) mode verification by selecting a button on the left side of a region 502 in FIG. 5.

The load mode is selected in FIG. 5. The program proceeds to step S209 in accordance with the input from the operator and determines whether the specified mode is the open-circuit mode. In this case, it is not the open-circuit mode; therefore, the program then proceeds to step S210 and the position on the ISS of the pad onto which the probe should touch down is obtained from the input in a region 506 in FIG. 5. The pad on the left side of row A, column 1 (represented by L in region 506) is specified as the position of the pad for load compensation on the screen in FIG. 5. The “L,” which shows the subject of load compensation, is displayed on an overlapping pad 507 for load compensation corresponding to the ISS layout of region 504.

It should be noted that in the case of short-circuit mode verification, the specified details of the SHORT row in region 506 are obtained as the subject of using the ISS and are reflected in region 504. That is, in FIG. 5 the “S,” which shows the subject of short-circuit compensation, is displayed overlapping a pad 505 on the left of row A, column 1 onto which the probe is to touch down for short-circuit compensation.

Next, the program proceeds to step S212 and the specified offset of the probing position shown in a region 508 of FIG. 5 is obtained. This is the load mode and therefore, the values for X, Y, and Z, which have been written under the “LOAD” column in region 508, are obtained. These X and Y values show whether the prober probes in directions X and Y with a difference of several microns from the standard coordinates used for the pad in question. The prober probes using as the reference a place that is several microns different in direction Z from the same standard coordinates, that is, using direction Z to specify the overdrive of the contact probe.

The X, Y and Z coordinates written under the column “SHORT” in region 508 are used for verification of the short-circuit mode.

In the past, the offset setting was not split up into a short-circuit mode and a load mode as with region 508. Therefore, it was necessary for the operator to control the prober manually and change the offset of the prober standard position each time the mode was switched for probing. In this case, the offset settings were erased and it became necessary to reset the coordinates every time the mode was changed. Moreover, it was necessary for the previous offset settings to be visible and this interfered with automation of compensation. By establishing this region 508, the present invention considerably automates the compensation.

Furthermore, in the past, the operator manually controlled not only the offset in the directions of the X and Y axes, but also the overdrive applied to the contact probe, that is, the load pressure. Nevertheless, by means of the present invention, the parameters corresponding to overdrive for both the short-circuit mode and the load mode are set as the offset in direction Z. This has an effect in terms of stability and high precision of the measurements, both for verification and for compensation.

A verify button 510 in FIG. 5 is pushed in step 214. It should be noted that when the program is in the open-circuit mode at step S209, it skips the above-mentioned two steps and proceeds to step S214. When the verify button is pushed and a command is given to execute the verification measurement, the program proceeds to step S216 and unless the program is in the open-circuit mode, it evaluates whether or not the number of contacts with the desired pad is within the limit. The limit can be separately set for the short-circuit mode and the load mode in this case, and can be a value read from a file at step S102 in FIG. 1 or a value set by the definition tab in step S108.

When the limit is exceeded, that is, the answer is “No,” at step S216, the program proceeds to step S218 and an alarm indicating that the limit has been exceeded is displayed. The program proceeds to step S206 and execution of verification ends.

When the value is within the limit, that is, the answer is “Yes,” at step S216, the program proceeds to step S220 and verification measurement is performed. Next, the program proceeds to step S222 and the measurement results are displayed in a region 512 of FIG. 5. The measurement results are converted to the values entered in the tabs that are arranged vertically and to the right in region 512 and the x-axis is displayed as frequency. |Z |, which shows the absolute impedance; Theta, which shows the phase; and Cp, Gp, Rs, and Ls, which show the conversion mode of impedance, are set at the tabs in region 512. Next, the program proceeds to step S224 and inputs whether or not the verification results are satisfactory. If the results are satisfactory (Yes), the program returns to step S204.

If it is input that the results are not satisfactory (No), the program proceeds to step S206 in order to repeat each setting and execution of verification ends.

After the other tabs have been set by mouse 742 or keyboard 738 at step S204, the program proceeds to step S206 and execution of verification ends.

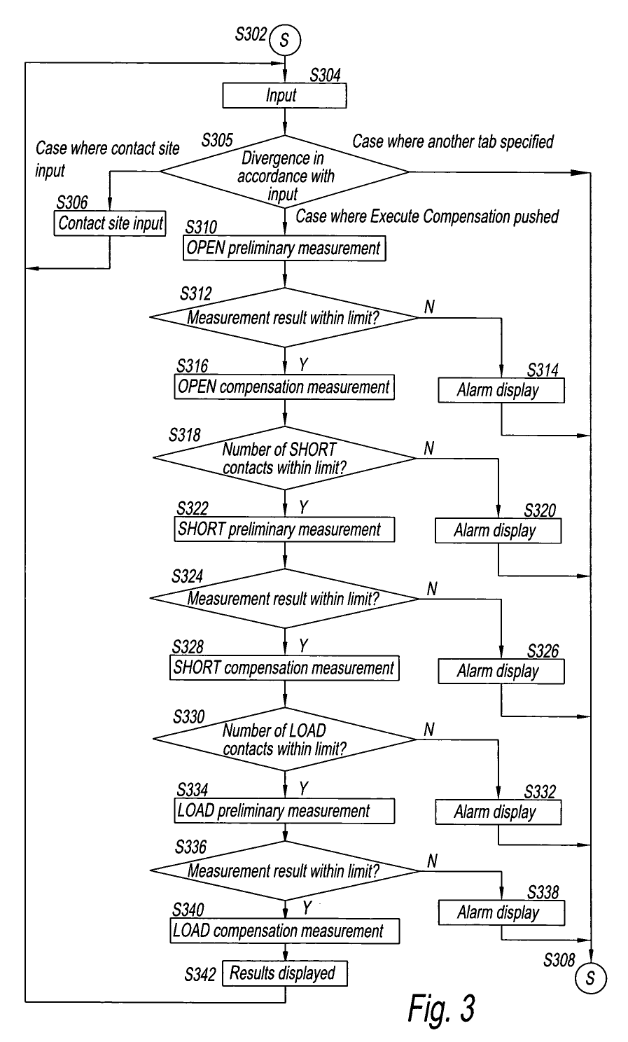

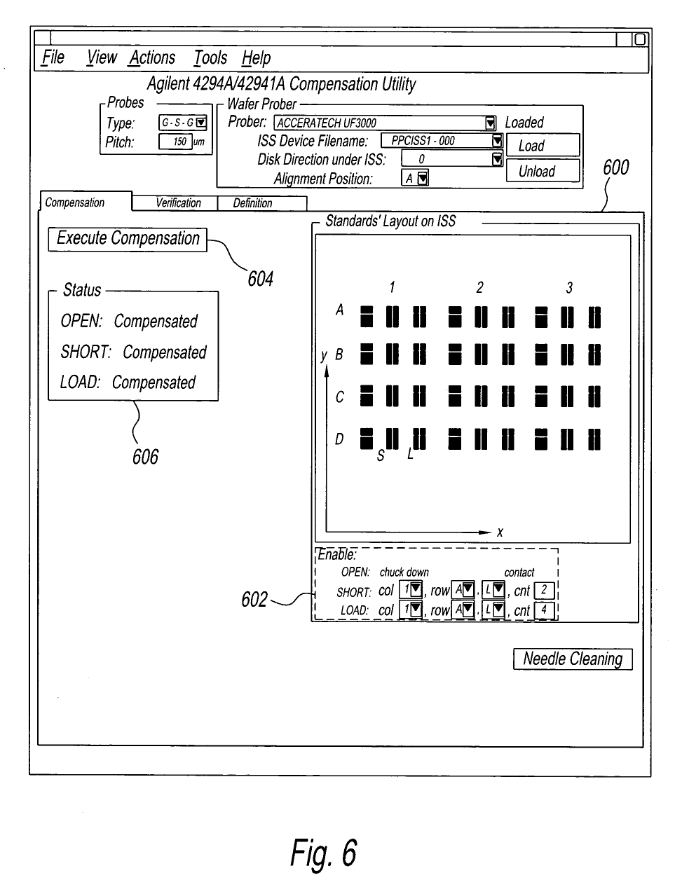

Next, the algorithm with the compensation tab in step S112 will be described using the flow chart of the algorithm in FIG. 3 and a screen 600 for the compensation tab in FIG. 6. The execution routine of the compensation tab is started at step S302. Input from the operator is obtained at step S304 and if there is input, the program proceeds to step S305 and diverges in accordance with the input. After the operator has input contact sites in a region 602 of FIG. 6, the program proceeds to step S306 and the settings for the input contact sites are obtained. The details of the settings in region 602 are the same as those for region 506 in FIG. 5 and a description is therefore omitted.

When the other tabs are specified by mouse 742 or keyboard 738 in step S304, the program proceeds to step S308 and the execution of compensation ends.

When an execute compensation button 604 in FIG. 6 is pushed at step S304, the program proceeds from step S305 to step S310. Compensation measurement is performed in the open-circuit mode at steps S310, S312, and S316. That is, a preliminary measurement in an open-circuit state, i.e., a preliminary measurement of the impedance, is performed at step S3 10 without touch-down by the contact probe. It takes time to carefully measure the impedance over a wide range; therefore, this preliminary measurement of impedance is conducted in a shorter time to verify that the measurement results are not obviously anomalous. For instance, preliminary measurement of the impedance is conducted at a low frequency of 1 kHz to 10 kHz. It is also possible to quickly estimate the impedance of the contact resistance component minus the effect of the residual inductor or parasitic capacitance of the measurement system by pre-measuring the impedance at such a low frequency.

Preliminary measurement is performed at step S310 and the program proceeds to step S312 where it evaluates whether or not the measurement result is within the preset limit range. If the measurement result is outside the range (No), the program proceeds to step S314 and an alarm is displayed. Then the program proceeds to step S308 and execution of compensation ends.

If it is within the preset range (Yes), the program proceeds to step S316, a compensation measurement in the open-circuit mode is performed, and the results are obtained and stored in memory 730.

Next, a compensation measurement in the short-circuit mode is performed at steps S318, S322, S324, and S326. That is, at step S318 the program evaluates whether, from that point on, the number of contacts with the pad onto which the contact probe touches down is within the limit based on the details in memory 730. When the number of contacts is within the limit (Yes), the program proceeds to step S322, the contact probe touches down on the desired pad, and the short-circuit mode preliminary measurement is performed. After touch-down, the number of contacts on the pad in question is increased by one and stored in memory 730. The measurement conditions for the preliminary measurement are the same as in the case of the open-circuit mode. Next, the program proceeds to step S324 and evaluates whether the measurement result of the preliminary measurement is within a predetermined limit. When the measurement result is within the limit (Yes), the program proceeds to step S328, a short-circuit mode preliminary measurement is performed on the pad with the probe left touching down, and the measurement result is obtained and stored in memory 730.

It should be noted that the program proceeds to step S320 or Step S326 when it is evaluated that the measurement result is outside the limit (No) in step S318 or Step S324, respectively, the alarm that indicates that the result is outside the limit is displayed, the program proceeds to step S308, and execution of verification stops.

The compensation measurement in the load mode is performed in steps S330, S334, S336, and S340. That is, at step S330 the program evaluates whether, from that point on, the number of contacts with the pad onto which the contact probe touches down is within the limit based on the details in memory 730. When the number of contacts is within the limit (Yes), the program proceeds to step S334, the contact probe touches down on the desired pad, and the short-circuit mode preliminary measurement is performed. After touch-down, the number of contacts on the pad in question is increased by one and stored in memory 730. The measurement conditions for preliminary measurement are the same as in the case of the open-circuit mode. Next, the program proceeds to step S336 and evaluates whether the measurement result of the preliminary measurement is within a predetermined limit. When the measurement result is within the limit (Yes), the program proceeds to step S340, a load compensation mode preliminary measurement is performed on the pad with the probe left touching down, and the measurement result is obtained and stored in memory 730. The results are then displayed in region 606 in FIG. 6 at step S342 and the program returns to step S304.

It should be noted that the program proceeds to step S332 or Step S338 when it is evaluated that the measurement result is outside the limit (No) in step S330 or Step S336, respectively, the alarm that indicates that the result is outside the limit is displayed, the program proceeds to step S308, and execution of compensation stops.

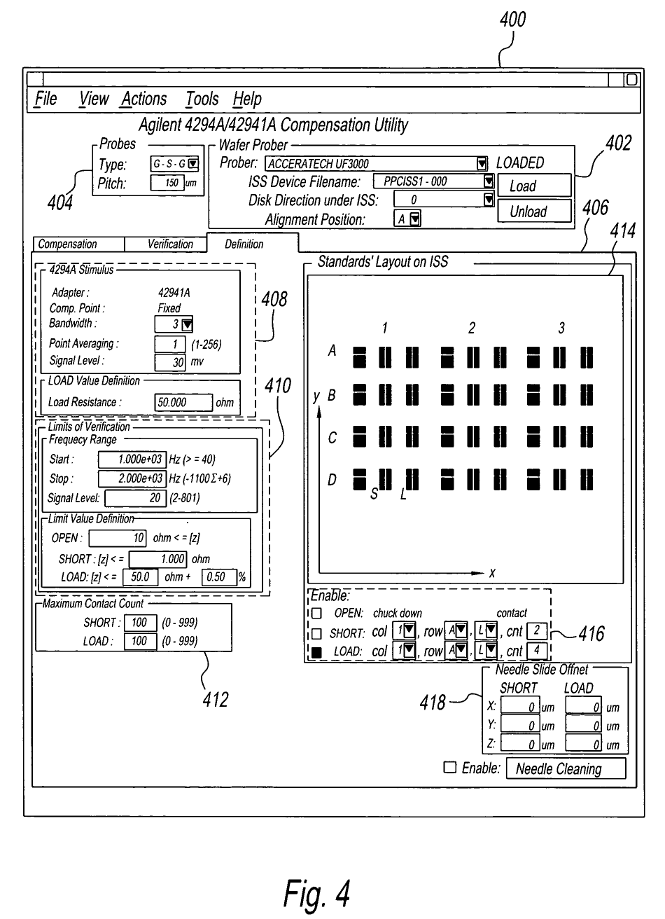

A screen 406 of the definition tab and the execution details of the screen will now be described while referring to FIG. 4. The definition tab creates the settings used by the verification and compensation tabs. Specification of the measurement bandwidth for the impedance measurement, the average number of contacts, the signal level, and the load are set in a region 408 of FIG. 4.

Moreover, the lower limit frequency, the upper limit frequency, and the number of measurement points between these frequencies for the impedance measurement, as well as the limit by open-circuit/short-circuit/load measurement for executing verification and for preliminary compensation measurement are set in a region 410. Furthermore, the limit to the number of contacts with the pads on the ISS is set for both the short-circuit mode and the load mode in a region 412. The position on the ISS of the pad that is used from that point on is specified in a region 416, and the deviation in directions X, Y, and Z of the pad specified in region 416 is set for both the short-circuit mode and the load mode in a region 418. It should be noted that regions 416 and 418 have the same function as regions 506 and 508 in FIG. 5; therefore, a description of these regions has been omitted. These settings are stored in memory 730 and can be referred to as needed for each of the routines.

A region represented as 402 in FIG. 4 displays the type of prober 702 being used, the type and position of ISS 704, and whether or not the ISS 704 is loaded in prober 702, and has a button for controlling loading/unloading. Moreover, a region 404 displays that the type of pad loaded on ISS 704 and used for compensation is the GSG-type and that the pitch between pads is 150 microns. The program of the present invention displays all of these data in a window 400. In addition, it can display any of the three tab screens for compensation, verification, and definition.

Embodiments of the present invention have been described, but various modifications are possible based on the concept of the present invention.

What is claimed is:

1. A measurement method for compensation or verification for short-circuit compensation or load compensation comprising:
inputting a contact site for probing the impedance standard substrate;
displaying an alarm when the number of contacts with said contact site exceeds a predetermined limit; and
measuring impedance by probing an impedance standard substrate with a contact probe when the number of contacts with said contact site does not exceeds the predetermined limit.

2. The method according to claim 1, wherein the number of contacts with the contact site is stored in a memory of a computer for controlling the contact probe and the device for measuring impedance.

3. The method according to claim 1, wherein the amount of offset for probing is specified after the step whereby said contact site is input.

4. The method according to claim 3, wherein the specification of the amount of offset includes the amount of offset in directions X, Y, and Z.

5. The method according to claim 3, wherein the amount of offset is specified, differentiating between whether it is for short-circuit compensation or load compensation.

6. A measurement method for verification comprising:
inputting a contact site for probing the impedance standard substrate;
isplaying an alarm when the number of contacts with said contact site exceeds a predetermined limit;
measuring impedance by probing an impedance standard substrate with a contact probe when the number of contacts with said contact site does not exceeds the predetermined limit; and
displaying the measurement results at the predetermined frequency in graph form after the verification measurement.

7. A measurement method for compensation, which is a measurement method for compensation at each compensation mode of open-circuit compensation, short-circuit compensation, and load compensation using a contact probe and an impedance standard substrate and a device for measuring impedance, said method comprising:
performing a preliminary measurement of impedance when conducting a compensation measurement of each of the three compensation modes; and
performing an impedance measurement for compensation calculation when these measurement values are within a first predetermined limit range.

8. A measurement method for compensation, which is a measurement method for compensation at each compensation mode of open-circuit compensation, short-circuit compensation, and load compensation using a contact probe and an impedance standard substrate and a device for measuring impedance, said method comprising:
performing a preliminary measurement of impedance when conducting a compensation measurement of each of the three compensation modes;
displaying an alarm during the compensation modes of the short-circuit compensation and load compensation before performing said preliminary impedance measurement if the number of contacts with a contact site probed by said contact probe exceeds a second predetermined limit; and
performing an impedance measurement for compensation calculation when these measurement values are within a first predetermined limit range.
(COMMENT from Shunichi to Paul: If you think that “first predetermined limit range in claim 8 can be different from that of claim 7, you can exchange words “first predetermined limit” and “second predetermined limit” in claim 8.)

9. A measurement method for compensation and verification, which is a measurement method for compensation and verification in each compensation mode of open-circuit compensation, short-circuit compensation, and load compensation using a contact probe and an impedance standard substrate and a device for measuring impedance, said method comprising:
performing a verification measurement; and
if the results of said verification measurement are within a predetermined limit range, performing a compensation measurement using contact conditions relating to said contact probe of said impedance standard substrate used for said verification measurement.

10. The method according to claim 9, wherein said contact conditions include specification of a contact site and specification of the amount of offset in the X, Y, and Z directions for both short-circuit and load compensation.
